(19) United States
(12) Patent Application Publication
(10) Pub. No.: US 2024/0318305 A1
(43) Pub. Date: Sep. 26, 2024

(54) METHOD FOR FORMING SILICON-CONTAINING FILM, AND SILICON-CONTAINING FILM FORMED THEREBY

(71) Applicant: UP CHEMICAL CO., LTD., Pyeongtaek-si, Gyeonggi-do (KR)

(72) Inventors: Byung Kwan KIM, Pyeongtaek-si (KR); Jin Sik KIM, Pyeongtaek-si (KR); Da Som YU, Pyeongtaek-si (KR)

(73) Assignee: UP CHEMICAL CO., LTD., Pyeongtaek-si, Gyeonggi-do (KR)

(21) Appl. No.: 18/577,875

(22) PCT Filed: Jul. 21, 2022
(86) PCT No.: PCT/KR2022/010713

§ 371 Date: Jan. 9, 2024

(30) Foreign Application Priority Data
Jul. 23, 2021 (KR) 10-2021-0097389

(51) Int. Cl. C23C 16/40; C23C 16/455; H01L 21/02

(52) U.S. Cl. CPC C23C 16/402; C23C 16/45527; H01L 21/02164; H01L 21/0228

(57) ABSTRACT

A method for forming a silicon-containing film and a silicon-containing film formed by the method are disclosed. The method for forming a silicon-containing film can use a composition for forming a silicon-containing film including a silicon precursor compound having a specific structure to efficiently form a silicon-containing film including a silicon-containing oxide film or a silicon-containing composite metal oxide film at a high temperature of 600° C. or more, control the silicon-containing film to have a thickness and composition of a desired film, and form a silicon-containing film having excellent coverage and uniformity even on a substrate with a complex shape.

### TECHNICAL FIELD

The present invention relates to a method for forming a silicon-containing film and a silicon-containing film prepared thereby. More specifically, it relates to a method for forming a silicon-containing film using a composition for forming a silicon-containing film comprising a silicon precursor compound having a specific structure at a high temperature of 600° C. or higher, and a silicon-containing film prepared thereby.

### BACKGROUND ART

A silicon-containing film is one of the thin films essential for driving non-semiconductor devices such as logic devices, as well as semiconductors such as DRAM, flash memory, resistive memory (ReRAM), or phase change memory (PCRAM).

As a silicon-containing film, a silicon-containing oxide film has a high deposition rate, whereas a silicon-containing nitride film has a slow deposition rate. For various applications, there is a demand for a silicon-containing film that can be selectively deposited only on a desired location.

In addition, as products having a complex shape such as a high aspect ratio and a three-dimensional structure are variously developed in the memory field and non-memory field, there is a demand for a composition for forming a silicon-containing film comprising a silicon precursor compound that can be used for atomic layer deposition (ALD), which is suitable for process temperatures for various application fields and can overcome a high step ratio.

In particular, it is important to exhibit self-limiting film growth characteristics in order to overcome the step ratio that may be caused by the high integration and scale down of the device.

Therefore, there is a demand for developing a composition for forming a thin film comprising a silicon precursor compound that has self-limiting film growth characteristics at a high temperature of 600° C. or higher, is suitable for ALD, is capable of forming a uniform and dense film, and has a characteristic resistant to stress; and for developing a method for forming a silicon-containing film using the same.

### PRIOR ART DOCUMENTS

### Patent Documents

(Patent Document 1) Korean Patent No. 10-0734393

### DISCLOSURE OF INVENTION

### Technical Problem

An object of the present invention is to provide a method for forming a silicon-containing film using a composition for forming a silicon-containing film comprising a silicon precursor compound having a specific structure at a high temperature of 600° C. or higher, and a silicon-containing film prepared thereby.

Another object of the present invention is to provide a composition for forming a silicon-containing film comprising a silicon precursor compound having a specific structure.

However, the problems to be solved by the present invention are not limited to those mentioned above, and other problems not mentioned will be clearly understood by those skilled in the art from the following description.

### Solution to the Problem

The present invention provides a method for forming a silicon-containing film, which comprises depositing a silicon-containing film on a substrate using a composition for forming a silicon-containing film comprising a silicon precursor compound represented by the following Formula 1 by chemical vapor deposition (CVD) or atomic layer deposition (ALD), wherein the silicon-containing film comprises at least one selected from the group consisting of a silicon-containing oxide film and a silicon-containing composite metal oxide film, and the deposition is carried out at a temperature of 600° C. or higher.

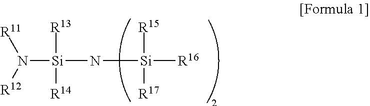

In Formula 1,
R¹¹ and R¹² are each independently selected from the group consisting of hydrogen and a linear or branched C₁-C₄ alkyl group, and
R¹³ to R¹⁷ are each independently selected from the group consisting of hydrogen, a linear or branched C₁-C₄ alkyl group, and a linear or branched C₂-C₆ alkenyl group,
provided that at least one of R¹³ and R¹⁴ is not hydrogen; and that at least one of R¹⁵ to R¹⁷ is not hydrogen.

In addition, the present invention provides a composition for forming a silicon-containing film, which comprises a silicon precursor compound represented by the above Formula 1 and used for depositing a silicon-containing film by chemical vapor deposition (CVD) or atomic layer deposition (ALD) at a temperature of 600° C. or higher, wherein the silicon-containing film comprises at least one selected from the group consisting of a silicon-containing oxide film and a silicon-containing composite metal oxide film.

In addition, the present invention provides a silicon-containing film formed by the method for forming a silicon-containing film.

### Advantageous Effects of Invention

The method for forming a silicon-containing film according to an embodiment of the present invention can efficiently form a silicon-containing film comprising at least one selected from the group consisting of a silicon-containing oxide film and a silicon-containing composite metal oxide film using a composition for forming a silicon-containing film comprising a silicon precursor compound having a specific structure at a high temperature of 600° C. or higher. It is possible to precisely control the desired film thickness and composition and to form a uniform silicon-containing film with excellent coverage even on a substrate having a complex shape.

In particular, the method for forming a silicon-containing film of the present invention can be applied to various fields such as moisture penetration barriers of memory devices, logic devices, display devices, and organic light emitting diode (OLED) devices. Since a film having a desired thickness can be obtained at a high temperature of 600° C. or higher during film deposition, it can be very effectively utilized in electronic devices that require excellent film properties and coverage.

### BRIEF DESCRIPTION OF DRAWINGS

FIG. 1 is a graph showing the deposition characteristics of a silicon-containing oxide film with respect to a temperature of 600° C. to 850° C. when the silicon-containing film is deposited using a composition for forming a silicon-containing film comprising each of the silicon precursor compounds of Examples 1 to 5 and 8 and Comparative Example 1 of the present invention.

FIG. 2 is a graph showing the results of secondary ion mass spectrometry (SIMS) of a silicon-containing oxide film deposited at a temperature of 750° C. using a composition for forming a silicon-containing film comprising each of the silicon precursor compounds of Examples 1 to 5 and Comparative Example 1 of the present invention.

FIG. 3 is a transmission electron microscope (TEM) image confirming the step coverage by depositing on a patterned wafer at 750° C. using a composition for forming a silicon-containing film comprising each of the silicon precursor compound of Example 2 and Comparative Example 1 of the present invention.

### BEST MODE FOR CARRYING OUT THE INVENTION

Hereinafter, the present invention will be described in detail.

The advantages and features of the present invention and the methods of achieving them will become apparent with reference to the embodiments described hereinafter. However, the present invention is not limited to the embodiments described below, but may be embodied in various different forms. These embodiments are provided so that the disclosure of the present invention will be thorough and complete, and will fully convey the scope of the invention to those skilled in the art. The invention is defined by only the scope of the claims.

In addition, in the present specification, in the case where an element is mentioned to be formed “on” another element, it means not only that one element is directly formed “on” another element, but also that other element(s) is interposed between them.

In the present specification, when a part is referred to as “comprising” an element, it is to be understood that the part may comprise other elements as well, rather than exclude other elements, unless otherwise indicated.

All numbers and expressions related to the quantities of components, reaction conditions, and the like used herein are to be understood as being modified by the term “about,” unless otherwise indicated.

In the present specification, each of the terms “film” and “thin film” refers to both “film” and “thin film,” unless otherwise specified.

In the present specification, the term “alkyl” or “alkyl group” covers linear or branched alkyl groups and all possible isomers thereof. For example, the alkyl or alkyl group covers not only a methyl group (Me), an ethyl group (Et), a normal propyl group (ⁿPr), an isopropyl group (ⁱPr), a normal butyl group (ⁿBu), an isobutyl group (ⁱBu), a tert-butyl group (tert-Bu, ^{t}Bu), sec-butyl group (^{sec}Bu), and the like, but also isomers thereof, and the like, but it is not limited thereto.

### [Method for Forming a Silicon-Containing Film]

According to an embodiment of the present invention, there may be provided a method for forming a silicon-containing film, which comprises depositing a silicon-containing film on a substrate using a composition for forming a silicon-containing film comprising a silicon precursor compound represented by the following Formula 1 by chemical vapor deposition (CVD) or atomic layer deposition (ALD), wherein the silicon-containing film comprises at least one selected from the group consisting of a silicon-containing oxide film and a silicon-containing composite metal oxide film, and the deposition is carried out at a temperature of 600° C. or higher.

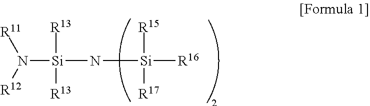

In Formula 1,
R¹¹ and R¹² are each independently selected from the group consisting of hydrogen and a linear or branched C₁-C₄ alkyl group, and
R¹³ to R¹⁷ are each independently selected from the group consisting of hydrogen, a linear or branched C₁-C₄ alkyl group, and a linear or branched C₂-C₆ alkenyl group,
provided that at least one of R¹³ and R¹⁴ is not hydrogen; and that at least one of R¹⁵ to R¹⁷ is not hydrogen.

According to the method for forming a silicon-containing film according to an embodiment of the present invention, it is possible to efficiently form a silicon-containing film comprising at least one selected from the group consisting of a silicon-containing oxide film and a silicon-containing composite metal oxide film using a composition for forming a silicon-containing film comprising a silicon precursor compound having a specific structure represented by Formula 1 at a high temperature of 600° C. or higher. It is possible to precisely control the desired film thickness and composition and to form a uniform silicon-containing film with excellent coverage even on a substrate having a complex shape.

In particular, the method for forming a silicon-containing film of the present invention has a technical significance in that it can be applied to various fields such as moisture penetration barriers of memory devices, logic devices, display devices, and organic light emitting diode (OLED) devices, and a film of a desired thickness can be obtained at a high temperature of 600° C. or higher during film deposition.

Specifically, in the method for forming a silicon-containing film, the formation of a silicon-containing film may comprise depositing a silicon-containing film using a composition for forming a silicon-containing film comprising the silicon precursor compound represented by Formula 1 on a substrate (board).

The substrate may be a silicon semiconductor wafer, a compound semiconductor wafer, and a plastic substrate (PI, PET, or PES), but it is not limited thereto. In addition, a substrate having holes or grooves may be used, and a porous substrate having a large surface area may be used.

In particular, it is possible to uniformly form a silicon-containing film having a thickness of several nanometers (nm) to several micrometers (μm) even on a substrate having patterns (grooves) on its surface, a porous substrate, or a plastic substrate in a temperature range of 600° C. or higher, specifically, 600° C. to 850° C. It is possible to produce an excellent effect of forming a silicon-containing film having a uniform thickness on a substrate, covering the deepest surface of fine patterns (grooves) and the upper surface of the fine irregularities (grooves) having an aspect ratio of 1 or more, for example, about 1 to 50 or more and a width of 1 μm or less, for example, about 1 μm to nm or less. For example, the silicon-containing film may be formed on a substrate having at least one irregularity having an aspect ratio of 1 or more and a width of 1 μm or less.

The deposition method of a silicon-containing film may use any methods and apparatuses known in the art to which the present invention pertains; if necessary, it may be carried out using one or more additional reactant gases or the like.

The deposition method of a silicon-containing film may be carried out by CVD, for example, organometallic chemical vapor deposition (MOCVD), or ALD. The MOCVD or ALD may be carried out using a deposition apparatus, deposition conditions, and reactive gases known in the art.

Specifically, a substrate is accommodated in a reaction chamber, a composition for forming a silicon-containing film comprising the silicon precursor compound is then transferred onto the substrate using a transport gas or a diluent gas, and a silicon-containing film is deposited at a deposition temperature of 600° C. or higher, specifically, 600° C. to 850° C.

Here, the deposition temperature of the above range allows it to be applied to memory devices, logic devices, and display devices. Since the process temperature is broad, it can be applied to various fields. In particular, as the composition for forming a silicon-containing film comprising the silicon precursor compound that is resistant to stress and capable of forming a dense film at a high temperature is used, deposition is readily carried out in the above deposition temperature range.

In addition, it is preferable to use at least one mixed gas selected from the group consisting of argon (Ar), nitrogen (N₂), helium (He), and hydrogen (H₂) as the transport gas or diluent gas.

In addition, the method of delivering the silicon precursor compound into the reaction chamber may be at least one method selected from the group consisting of a bubbling method in which the composition for forming a silicon-containing film comprising the silicon precursor compound is forcibly vaporized using a transport gas or a diluent gas; a liquid delivery system (LDS) method for supplying it in a liquid phase at room temperature to be vaporized through a vaporizer; a vapor flow control (VFC) method for directly supplying the precursor using its vapor pressure; and a bypass method for vaporization by heating.

For example, if the vapor pressure is high, a vapor flow control method may be used. If the vapor pressure is low, a bypass method of vaporization by heating the vessel or a method of bubbling using argon (Ar) or nitrogen (N₂) gas may be used to supply the composition for forming a silicon-containing film comprising the silicon precursor compound into the reaction chamber.

More specifically, the delivery method comprises a bubbling method or a bypass method, in which the bubbling method may be carried out using a transport gas or diluent gas in a temperature range of room temperature to 150° C. and 0.1 Torr to 10 Torr, and the bypass method may be carried out using a vapor pressure of 0.1 Torr to 1.5 Torr in a temperature range of room temperature to 100° C. For example, the supply of the composition for forming a silicon-containing film comprising the silicon precursor compound into the reaction chamber may be carried out using a transport gas or diluent gas in a temperature range of room temperature to 100° C. and 0.1 Torr to 10 Torr.

In addition, in order to vaporize the composition for forming a silicon-containing film comprising the silicon precursor compound, for example, argon (Ar) or nitrogen (N₂) gas may be used for transportation thereof, thermal energy or plasma may be used during deposition, or a bias may be applied onto the substrate.

Meanwhile, according to the method of forming a silicon-containing film, in order to deposit at least one silicon-containing film selected from the group consisting of a silicon-containing oxide film or a silicon-containing composite metal oxide film, at least one selected from the group consisting of water vapor (H₂O), oxygen (O₂), oxygen plasma (O₂ plasma), nitric oxide (NO, N₂O), nitric oxide plasma (N₂O plasma), oxygen nitrate (N₂O₂), hydrogen peroxide (H₂O₂), and ozone (O₃) may be used during deposition.

The at least one silicon-containing film selected from the group consisting of a silicon-containing oxide film or a silicon-containing composite metal oxide film may comprise at least one selected from the group consisting of, for example, HfSiOₓ, ZrSiOₓ, TiSiOₓ, HfAlOₓ, ZrAlSiOₓ, TiAlSiOₓ, ZrHfSiOₓ, ZrHfAlSiOₓ, SiC, SiCO, and SiON, but it is not limited thereto. Here, x may be 1 to 3.

In addition, at least one silicon-containing film selected from the group consisting of a silicon-containing nitride film or a silicon-containing composite metal nitride film may be formed by using a composition for forming a silicon-containing film comprising the silicon precursor compound represented by Formula 1.

Specifically, in order to deposit a silicon-containing nitride film or a silicon-containing composite metal nitride film, at least one selected from the group consisting of ammonia (NH₃), ammonia plasma (HN₃ plasma), hydrazine (N₂H₄), and nitrogen plasma (N₂ plasma) may be used during deposition.

The silicon-containing nitride film or the silicon-containing composite metal nitride film may comprise at least one selected from the group consisting of, for example, HfSiNₓ, ZrSiNₓ, TiSiNₓ, AlSiNₓ, HfAlSiNₓ, ZrAlSiNₓ, TiAlSiNₓ, HfZrAlSiNₓ, HfZrTiSiNₓ, TiAlSiNₓ, SiCN, SiOCN, and SiBN, but it is not limited thereto. Here, x may be 1 to 3.

The composition for forming a silicon-containing film, which comprises the silicon precursor compound represented by the above Formula 1, will be described below in detail.

### [Composition for Forming a Silicon-Containing Film]

The present invention provides a composition for forming a silicon-containing film, which comprises a silicon precursor compound represented by the following Formula 1.

Specifically, the composition for forming a silicon-containing oxide film comprises a silicon precursor compound represented by the above Formula 1 and can be used for depositing a silicon-containing film by chemical vapor deposition (CVD) or atomic layer deposition (ALD) at a temperature of 600° C. or higher, wherein the silicon-containing film comprises at least one selected from the group consisting of a silicon-containing oxide film and a silicon-containing composite metal oxide film.

As the composition for forming a silicon-containing film according to an embodiment of the present invention comprises the silicon precursor compound having a specific structure represented by Formula 1, it is possible to form a uniform silicon-containing film, specifically silicon-containing oxide film, having excellent coverage even on a substrate having a complex shape.

In particular, as the above Formula 1 has a structure in which various types of amines and alkyl groups are bonded to Si, and, in particular, at least one of R¹³ and R¹⁴ in R¹³—Si—R¹⁴ among various types of bonds is not hydrogen, it is very advantageous for forming a stable film even at a high temperature of 600° C. to 850° C.

That is, in the silicon precursor compound represented by Formula 1, first, the amine represented by —NR¹¹R¹² in the above structure has excellent surface reactivity, which is advantageous for forming a silicon-containing oxide film; second, as at least one of R¹³ and R¹⁴ in the moiety represented by R¹³—Si—R¹⁴ in the above structure is not hydrogen, that is, at least one of R¹³ and R¹⁴ has an alkyl group or an alkenyl group, preferably, at least one of R¹³ and R¹⁴ has an alkyl group, the thermally stable bonding of Si and C makes it possible to form a stable film without rapidly decomposing the silicon precursor at high temperatures, so that it may be suitable for a three-dimensional NAND flash memory process that requires characteristics of a silicon-containing film at high temperatures; and third, the structure contains three Si elements and has a significantly larger GPC in SiO₂ ALD than that of the conventionally known silicon precursor compounds, so that it may be suitable for a three-dimensional NAND flash memory process in which a thick SiO₂ film is to be formed at high temperature.

Specifically, in Formula 1, R¹¹ and R¹² are each independently selected from the group consisting of hydrogen and a linear or branched C₁-C₄ alkyl group, and R¹³ to R¹⁷ are each independently selected from the group consisting of hydrogen, a linear or branched C₁-C₄ alkyl group, and a linear or branched C₂-C₆ alkenyl group, provided that at least one of R¹³ and R¹⁴ is not hydrogen; and that at least one of R¹⁵ to R¹⁷ is not hydrogen.

The silicon precursor compound may comprise at least one selected from the group consisting of compounds represented by the following Formulae 1-1 to 1-25:

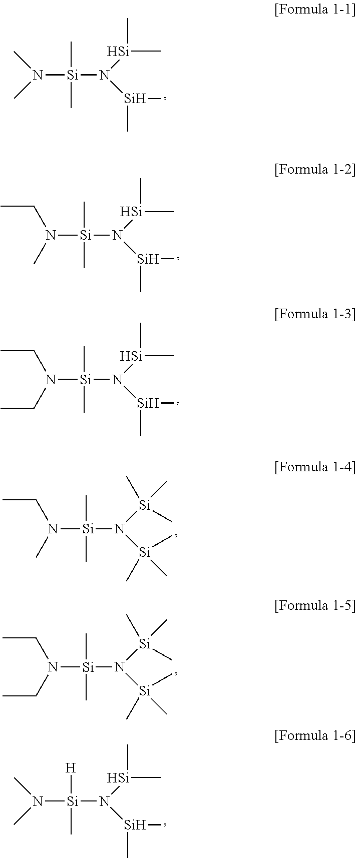

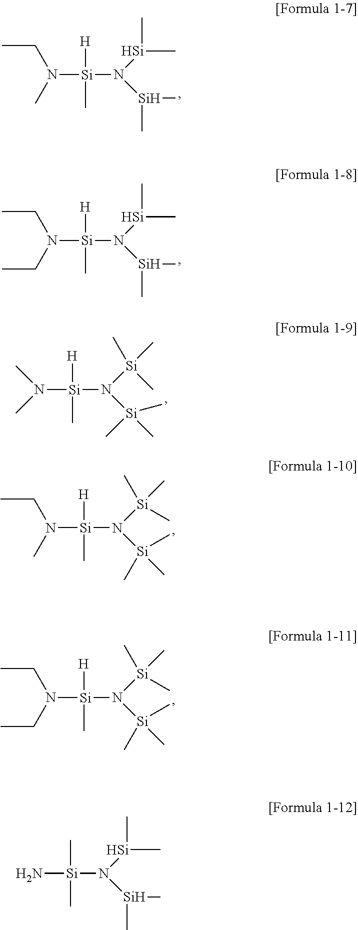

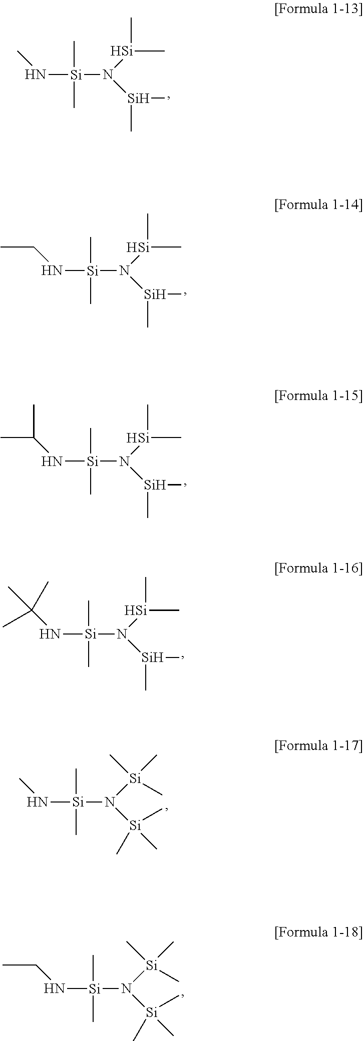

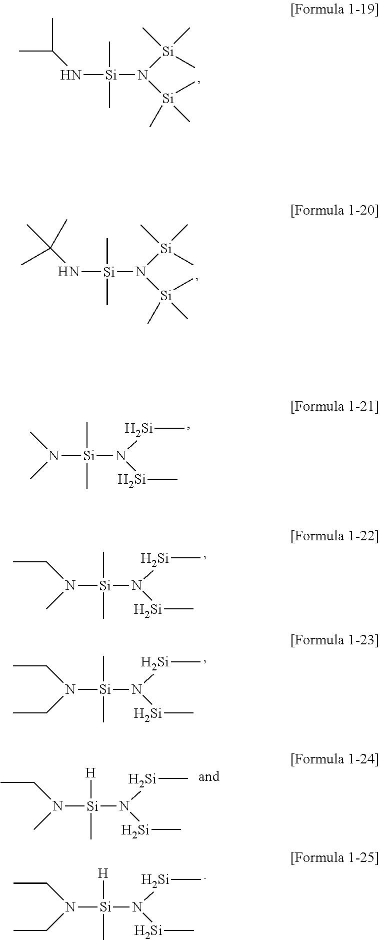

According to another embodiment of the present invention, the silicon precursor compound contained in the composition for forming a silicon-containing oxide film may be a compound represented by the following formula 1-a:

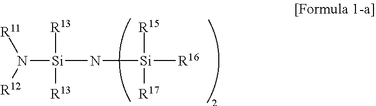

In Formula 1-a,
R¹¹ and R¹² are each independently a linear or branched C₁-C₄ alkyl group,
R¹³ to R¹⁷ are each independently selected from the group consisting of hydrogen, a linear or branched C₁-C₄ alkyl group, and a linear or branched C₂-C₆ alkenyl group,
provided that at least one of R¹¹ and R¹² is not a methyl group; that at least one of R¹³ and R¹⁴ is not hydrogen; and that at least one of R¹⁵ to R¹⁷ is not hydrogen.

Specifically, the silicon precursor compound may comprise at least one selected from the group consisting of compounds represented by the above Formulae 1-2 to 1-5, 1-7, 1-8, 1-10, 1-11, 1-13 to 1-20, and 1-22 to 1-25.

That is, the silicon precursor compound may comprise at least one selected from the group consisting of compounds represented by the following Formulae.

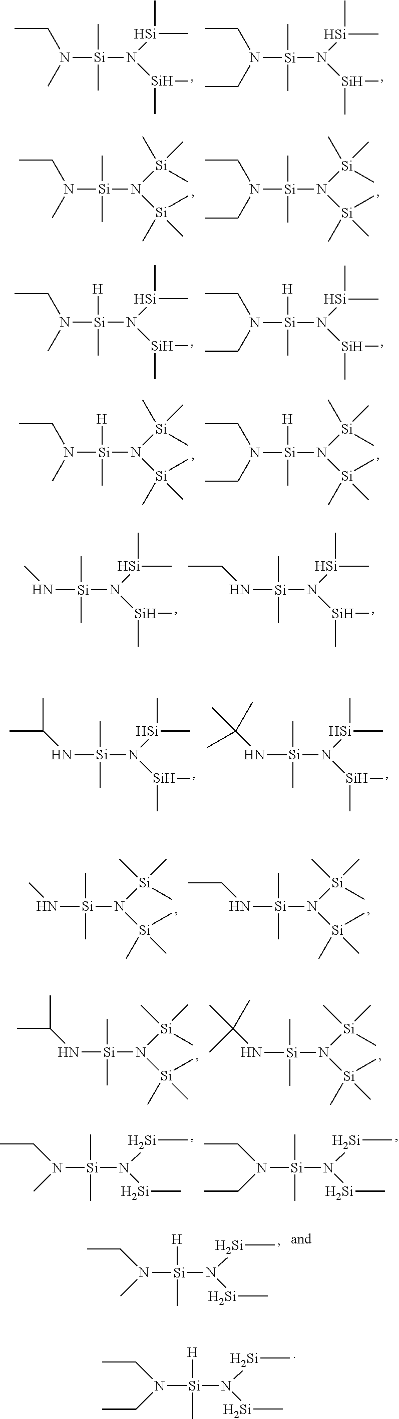

According to an embodiment of the present invention, when a deposition is carried out by ALD using the composition for forming a silicon-containing film, it may have a growth per cycle (GPC) of ALD gas supply of 1.5 to 3.0 Å/cycle in a temperature range of 600° C. to 850° C.

Specifically, when a deposition is carried out by ALD using the composition for forming a silicon-containing film, it is possible to achieve a growth per cycle (GPC) values of ALD gas supply of, for example, 1.5 to 2.5 Å/cycle, 1.7 to 2.5 Å/cycle, or 1.75 to 2.25 Å/cycle in a temperature range of 600° C. to 850° C., for example, at 800° C.

If a silicon-containing film is formed using the composition for forming a silicon-containing film according to an embodiment of the present invention, it is possible to control the composition to achieve a desired film thickness and a desired silicon content and to form a film having excellent coverage and uniform thickness even on a substrate having patterns (grooves) on its surface, a porous substrate, a plastic substrate, or a substrate having a complex shape of a three-dimensional structure, whereby it is possible to provide a silicon-containing film of high quality.

In addition, it is possible to efficiently form at least one selected from the group consisting of a silicon-containing nitride film, a silicon-containing carbide film, and a silicon-containing composite metal film, in addition to a silicon-containing film comprising at least one selected from the group consisting of a silicon-containing oxide film and a silicon-containing composite metal oxide film, on a substrate by CVD or ALD using the composition for forming a silicon-containing film.

In particular, according to an embodiment of the present invention, when a silicon-containing film comprising at least one selected from the group consisting of a silicon-containing oxide film and a silicon-containing composite metal oxide film is formed on a substrate by ALD using the composition for forming a silicon-containing film, there are great advantages in that a film having a desired thickness can be obtained with a uniform thickness at a high temperature of 600° C. or higher, the film shrinkage and the etch rate at a high temperature are lower, and a pure silicon-containing film of high quality with less impurities can be formed.

### [Method for Preparing a Silicon Precursor Compound]

Meanwhile, the silicon precursor compound represented by Formula 1 may be prepared by various methods.

The method for preparing a silicon precursor compound (Formula 1) according to an embodiment of the present invention comprises subjecting an alkyldisilazane metal salt represented by the following Formula A to a halide-amine substitution reaction with a dihalide silicon precursor compound represented by the following Formula B and a dialkylamine or a dialkylamine metal salt represented by the following Formula C:

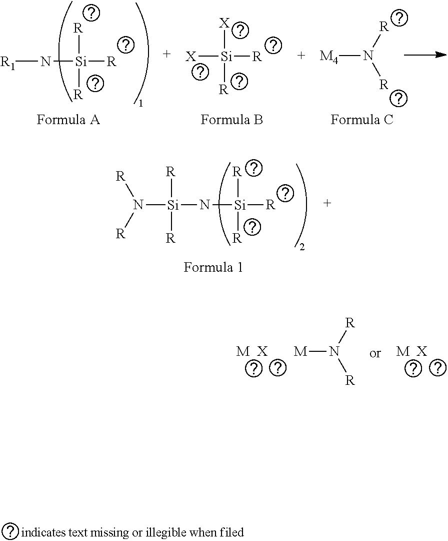

In Reaction Scheme 1,
M₃ is an alkali metal and Li or Na,
R¹⁵ to R¹⁷ are each independently selected from the group consisting of hydrogen, a linear or branched C₁-C₄ alkyl group, and a linear or branched C₂-C₆ alkenyl group, provided that at least one of R¹⁵ to R¹⁷ is not hydrogen,
X₃ and X₂ are each independently a halogen element and Cl, Br, or I,
R¹³ and R¹⁴ are each independently selected from the group consisting of hydrogen, a linear or branched C₁-C₄ alkyl group, and a linear or branched C₂-C₆ alkenyl group, provided that at least one of R¹³ and R¹⁴ is not hydrogen,
R¹¹ and R¹² are each independently hydrogen or a linear or branched C₁-C₄ alkyl group, and
M₄ is selected from the group consisting of hydrogen, Li, and Na.

Referring to Reaction Scheme 1 above, 0.5 to 2 moles of a dihalide silicon precursor compound (Formula B) are added to an alkyldisilazane metal salt (Formula A) at a low temperature (about −30° C. to −5° C.), and the silicon precursor compound (Formula 1) is subjected to a first substitution reaction of halide and amine. Thereafter, 1 to 3 moles of a dialkylamine or a dialkylamine metal salt (Formula C) is added to the resultant at a low temperature (about −30° C. to −5° C.) to carry out a second substitution reaction of halide and amine. Next, the reaction by-products in the form of a metal halide salt or a dialkylamine halide salt contained in the reaction product are removed through a filter, and the resultant may be purified to obtain the silicon precursor compound represented by Formula 1.

Here, when R¹³ and R¹⁴ in the structure of R¹³—Si—R¹⁴ in Reaction Scheme 1 are each an alkyl group, the rate of the substitution reaction between the halide and amine may be relatively slow. In such an event, the higher the reaction temperature, the easier the substitution reaction may be carried out, which may be more advantageous.

The first and second halide-amine substitution reactions may be carried out in a solvent at 0° C. to 30° C., specifically 20° C. to 30° C., for example, at room temperature for 2 to 30 hours.

In addition, the solvent may comprise one or more selected from the group consisting of an alkane having 5 to 8 carbon atoms, toluene, ether, tetrahydrofuran, and mono- to tetra-ethylene glycol dimethyl ether.

According to an embodiment of the present invention, the silicon precursor compound may be used to obtain a composition for forming a silicon-containing film comprising the silicon precursor compound.

### [Silicon-Containing Film]

According to an embodiment of the present invention, there is provided a silicon-containing film formed by the method for forming a silicon-containing film.

The silicon-containing film may have a thickness of several nanometers (nm) to several micrometers (μm) and may be variously applied depending on the application purposes. Specifically, the silicon-containing film may be formed in a thickness range of 1 nm to 500 nm.

The silicon-containing film may be formed on a substrate (board).

The substrate is as described above.

The silicon-containing film may comprise at least one selected from the group consisting of a silicon-containing oxide film and a silicon-containing composite metal oxide film.

In addition, it is possible to efficiently form at least one selected from the group consisting of a silicon-containing nitride film, a silicon-containing carbide film, and a silicon-containing composite metal film, in addition to a silicon-containing film comprising at least one selected from the group consisting of a silicon-containing oxide film and a silicon-containing composite metal oxide film, using the composition for forming a silicon-containing film comprising the silicon precursor compound represented by Formula 1.

In addition, as the silicon-containing film is prepared by using a composition for forming a silicon-containing film comprising a silicon precursor compound having excellent thermal stability, the silicon-containing film is characterized in that it has a low shrinkage even at a high temperature of 600° C. or higher, for example, 600° C. to 850° C., and a low wet etch rate (Å/s).

Specifically, the silicon-containing film may have a shrinkage (S₇₅₀) of 5.0% or less as represented by the following Equation 1:

$$Shrinkage ( {S}_{750} , \% ) = \frac{A - B}{A} \times 100 \qquad [ Equation 1 ]$$

In Equation 1, A is the initial thickness (Å) of a silicon-containing film formed by ALD at 750° C., and B is the thickness (Å) of the silicon-containing film formed by ALD at 750° C. after it is left at 750° C. in an argon (Ar) atmosphere for 60 minutes.

The shrinkage (S₇₅₀) of the silicon-containing film as represented by Equation 1 may be, for example, 4.8% or less, 4.5% or less, 4.4% or less, 4.0% or less, 3.9% or less, 3.8% or less, 3.5% or less, 3.3% or less, 3.2% or less, 3.0% or less, 2.5% or less, 2.0% or less, 1.5% or less, or 1.0% or less.

If the silicon-containing film has a shrinkage (S₇₅₀) satisfying the above range, it may be advantageous for forming a uniform and dense silicon-containing film.

Meanwhile, when the silicon-containing film is formed by deposition at 750° C. to a thickness of 500 Å, and when the thickness of the silicon-containing film is measured with an ellipsometer before and after the silicon-containing film is exposed to an etching solution of 1% dilute hydrofluoric acid, the wet etch rate (Å/s) of the silicon-containing film represented by the following Equation 2 may be 4.0 Å/s or less:

Wet etch rate(Å/s)=etch thickness change(ΔE,Å)/30s [Equation 2]

The etch thickness change (ΔE) may be represented by the following Equation 2-1:

$$Etch thickness change ( Δ E , Å ) = {E}_{A} - {E}_{B} \qquad [ Equation 2 ‐ 1 ]$$

In Equation 2-1, E_{A} is the initial thickness (Å) of a silicon-containing film formed by ALD at 750° C., and E_{B} is the thickness (Å) of the silicon-containing film formed by ALD at 750° C. after it is etched in a 1% dilute HF solution for 30 seconds.

In Equation 2, “s” means seconds.

The wet etch rate (Å/s) of the silicon-containing film as represented by Equation 2 may be, for example, 3.8 Å/s or less, 3.5 Å/s or less, 3.2 Å/s or less, 3.0 Å/s or less, 2.8 Å/s or less, 2.5 Å/s or less, 2.45 Å/s or less, 2.4 Å/s or less, 2.2 Å/s or less, 2.1 Å/s or less, 2.0 Å/s or less, 1.5 Å/s or less, 1.0 Å/s or less, 0.5 Å/s or less, 0.1 Å/s or less, 0.05 Å/s or less, or 0.03 Å/s or less. Specifically, the wet etch rate (Å/s) of the silicon-containing film as represented by Equation 2 may be 3.8 Å/s to 0.5 Å/s, 3.5 Å/s to 0.5 Å/s, 3.0 Å/s to 1.0 Å/s, 2.5 Å/s to 1.0 Å/s, or 2.1 Å/s to 1.0 Å/s.

If the silicon-containing film has a wet etch rate (Å/s) satisfying the above range, it may be advantageous for forming a uniform and dense silicon-containing film.

In addition, the silicon-containing film may be very excellent in step coverage.

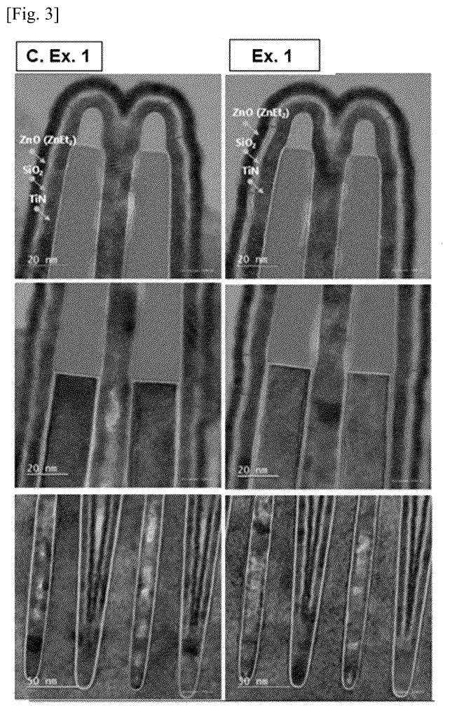

Specifically, when a silicon-containing film is deposited on a substrate having a stepped hole pattern as shown in FIG. 3 and then analyzed using a transmission electron microscope (TEM), the silicon-containing film has a step coverage (%) of, for example, 80% or more, for example, 82% or more, for example, 85% or more, for example, 90% or more, for example, 92% or more, for example, 93% or more, for example, 95% or more, or, for example, 96% or more.

If the silicon-containing film has a step coverage (%) satisfying the above range, high step ratio and fine thickness control are possible, so that it can be advantageously used to manufacture various semiconductor devices such as DRAM and 3D NAND flash memory.

### MODE FOR THE INVENTION

Hereinafter, the present invention will be described in detail with reference to examples. The following examples are only illustrative of the present invention, and the scope of the present invention is not limited thereto.

### EXAMPLE

<Example 1> Preparation of dimethylamino-(tetramethyldisilyl)amino-dimethylsilane and a composition for forming a silicone-containing film comprising the same: [{(CH₃)₂N}Si(CH₃)₂{N(SiHMe₂)₂}]

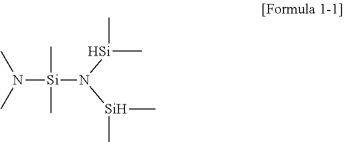

About 118.69 g (2.5 M, about 0.426 mole) of an n-butyllithium hexane solution (n-BuLi in n-hexane) was mixed with about 1,000 ml of anhydrous hexane in a 2-liter round bottom flask. About 61.99 g (about 0.465 mole) of tetramethyldisilazane (1,1,3,3-tetramethyldisilazane) was added thereto at about −20° C., and the temperature was then gradually raised to room temperature under stirring, followed by stirring thereof for 4 hours. About 50 g (about 0.387 mole) of dichlorodimethylsilane was slowly added to the lithium (1,1,3,3-tetramethyldisilazane) salt thus formed at −20° C. to −10° C., and the temperature was then gradually raised to room temperature under stirring, followed by stirring thereof for 4 hours. 4 hours later, about 41.91 g (about 0.930 mole) of dimethylamine was added thereto at about −20° C., and the temperature was then gradually raised to room temperature under stirring, followed by stirring thereof for 17 hours. Upon completion of the reaction, the salt formed during the reaction was removed through filtration, and the solvent and volatile side reactants were removed under a reduced pressure to obtain 59.97 g (yield: about 66%) of dimethylamino-(tetramethyldisilyl)amino-dimethylsilane [{(CH₃)₂N}Si(CH₃)₂{N(SiHMe₂)₂}] as a colorless liquid compound represented by Formula 1-1, which was used for a composition for forming a film.

b.p.: 72° C. at 10 Torr (194.5° C. at 760 Torr)

¹H-NMR (C₆D₆): δ 0.221 (Si—CH₃, s, 6H), δ 0.249, 0.241 (N—Si—CH₃, d, 12H), δ 2.424 (N—CH₃, s, 6H), δ 4.700 (N—Si—H, m, 2H)

<Example 2> Preparation of ethylmethylamino-(tetramethyldisilyl)amino-dimethylsilane and a composition for forming a silicone-containing film comprising the same: [{(CH₃CH₂)(CH₃)N}Si(CH₃)₂{N(SiHMe₂)₂}]

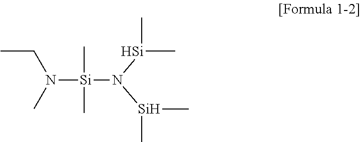

About 62.6 g (yield: about 65%) of ethylmethylamino-(tetramethyldisilyl)amino-dimethylsilane [{(CH₃CH₂)(CH₃)N}Si(CH₃)₂{N(SiHMe₂)₂}] as a colorless liquid compound represented by Formula 1-2 was obtained in the same manner as in Example 1, except that ethylmethylamine was used instead of dimethylamine, and it was used for the composition for film formation.

b.p.: 76° C. at 10 Torr (199.4° C. at 760 Torr)

¹H-NMR (C₆D₆): δ 0.235 (Si—CH₃, s, 6H), δ 0.257, 0.248 (N—Si—CH₃, d, 12H), δ 0.981 (N—CH₂—CH₃, t, 3H), δ 2.425 (N—CH₃, s, 3H), δ 2.774 2.756 (N—CH₂—CH₃, q, 2H), δ 4.722 (N—Si—H, m, 2H)

<Example 3> Preparation of ethylmethylamino-(hexamethyldisilyl)amino-dimethylsilane and a composition for forming a silicone-containing film comprising the same: [{(CH₃CH₂)(CH₃)N}Si(CH₃)₂{N(SiMe₃)₂}]

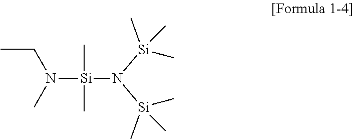 [SMILES: CCN(C)[Si](C)(C)N([Si](C)(C)C)[Si](C)(C)C]

About 71.81 g (yield: about 67%) of ethylmethylamino-(hexamethyldisilyl)amino-dimethylsilane [{(CH₃CH₂)(CH₃)N}Si(CH₃)₂{N(SiMe₃)₂}] as a colorless liquid compound represented by Formula 1-4 was obtained in the same manner as in Example 1, except that hexamethyldisilazane (1,1,1,3,3,3-hexamethyldisilazane) was used instead of tetramethyldisilazane (1,1,3,3-tetramethyldisilazane) and that ethylmethylamine was used instead of dimethylamine, and it was used for the composition for film formation.

b.p.: 35° C. at 0.3 Torr (216.3° C. at 760 Torr)

¹H-NMR (C₆D₆): δ 0.236 (Si—CH₃, s, 6H), δ 0.273 (N—Si—CH₃, s, 18H), δ 0.968 (N—CH₂—CH₃, t, 3H), δ 2.366 (N—CH₃, s, 3H), δ 2.722, 2.704 (N—CH₂—CH₃, q, 2H)

<Example 4> Preparation of diethylamino-(hexamethyldisilyl)amino-dimethylsilane and a composition for forming a silicone-containing film comprising the same: [{(CH₃CH₂)₂N}Si(CH₃)₂{N(SiMe₃)₂}]

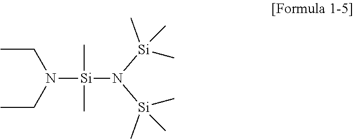 [SMILES: CCN(CC)[Si](C)(C)N([Si](C)(C)C)[Si](C)(C)C]

118.69 g (2.5 M, 0.426 mole) of an n-butyllithium hexane solution (n-BuLi in n-hexane) was mixed with about 500 ml of anhydrous hexane in a 3-liter round bottom flask. About 75.03 g (about 0.465 mole) of hexamethyldisilazane (1,1,1,3,3,3-hexamethyldisilazane) was added thereto at about −20° C., and the temperature was then gradually raised to room temperature under stirring, followed by stirring thereof for 4 hours. About 50 g (about 0.387 mole) of dichlorodimethylsilane was slowly added to the lithium (1,1,1,3,3,3-hexamethyldisilazane) salt solution thus formed at −20° C. to −10° C., and the temperature was then gradually raised to room temperature under stirring, followed by stirring thereof for 17 hours.

About 118.69 g (2.5 M, about 0.426 mole) of an n-butyllithium hexane solution (n-BuLi in n-hexane) was mixed with about 500 ml of anhydrous hexane in a 1-liter round bottom flask. About 34 g (about 0.465 mole) of diethylamine was added thereto at about −20° C., and the temperature was then gradually raised to room temperature under stirring, followed by stirring thereof for 4 hours. The lithium (diethylamine) salt solution thus formed was added to the 3-liter round bottom flask at about −20° C., and the temperature was then gradually raised to room temperature under stirring, followed by stirring thereof for 17 hours. Upon completion of the reaction, the salt formed during the reaction was removed through filtration, and the solvent and volatile side reactants were removed under a reduced pressure to obtain about 79.95 g (yield: about 71%) of diethylamino-(hexamethyldisilyl)amino-dimethylsilane [{(CH₃CH₂)₂N}Si(CH₃)₂{N(SiMe₃)₂}] as a colorless liquid compound represented by Formula 1-5, which was used for a composition for forming a film.

b.p.: 45° C. at 0.3 Torr (230.4° C. at 760 Torr)

¹H-NMR (C₆D₆): δ 0.262 (Si—CH₃, s, 6H), δ 0.283 (N—Si—CH₃, s, 18H), δ 0.976 (N—CH₂—CH₃, t, 6H), δ 2.806, 2.788 (N—CH₂—CH₃, q, 4H)

<Example 5> Preparation of N,N-bis(dimethylsilyl)-1,1-dimethylsilanediamine and a composition for forming a silicone-containing film comprising the same: [(H₂N)Si(CH₃)₂{N(SiHMe₂)₂}]

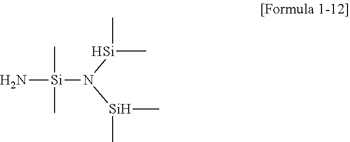

About 118.69 g (2.5 M, about 0.426 mole) of an n-butyllithium hexane solution (n-BuLi in n-hexane) was mixed with about 1,000 ml of anhydrous hexane in a 3-liter round bottom flask. About 61.99 g (about 0.465 mole) of tetramethyldisilazane (1,1,3,3-tetramethyldisilazane) was added thereto at about-20° C., and the temperature was then gradually raised to room temperature under stirring, followed by stirring thereof for 4 hours. About 50 g (about 0.387 mole) of dichlorodimethylsilane was slowly added to the lithium (1,1,3,3-tetramethyldisilazane) salt thus formed at −20° C. to −10° C., and the temperature was then gradually raised to room temperature under stirring, followed by stirring thereof for 4 hours. 4 hours later, about 32.99 g (about 1.937 moles) of ammonia gas was added thereto at about −78° C., and the temperature was then gradually raised to room temperature under stirring, followed by stirring thereof for 17 hours. Upon completion of the reaction, the salt formed during the reaction was removed through filtration, and the solvent and volatile side reactants were removed under a reduced pressure to obtain 62.40 g (yield: about 78%) of N,N-bis(dimethylsilyl)-1,1-dimethylsilanediamine [(H₂N)Si(CH₃)₂{N(SiHMe₂)₂}] as a colorless liquid compound represented by Formula 1-12, which was used for a composition for forming a film.

b.p.: 54° C. at 10 Torr (172.3° C. at 760 Torr)

¹H-NMR (C₆D₆): δ 0.202 (Si—CH₃, s, 6H), δ 0.269, 0.261 (N—Si—CH₃, d, 12H), δ 0.373 (NH₂, m, 2H), δ 4.768 (N—Si—H, m, 2H)

### Comparative Example 1

Tris(dimethylamido)silane (3DMAS or TDMAS) [SiH(NMe₂)₃] (manufactured by UP Chemical Co., Ltd.) was used.

### Test Example

### <Test Example 1> Analysis of the Deposition Characteristics at High Temperatures of a Composition for Forming a Silicon-Containing Film Comprising a Silicon Precursor Compound

A composition for forming a silicon-containing film comprising each of the silicon precursor compounds of the Examples and Comparative Examples and ozone (O₃) as a reaction gas were used to form a silicon-containing film by ALD.

First, a silicon substrate was immersed in Piranha solution in which sulfuric acid (H₂SO₄) and hydrogen peroxide (H₂O₂) had been mixed at a ratio of 4:1 for about 10 minutes and then taken out. It was then immersed in a dilute aqueous HF solution for 2 minutes to form a fresh surface. A silicon-containing oxide film was then formed on the silicon substrate by ALD.

A composition for forming a silicon-containing film comprising a silicon precursor compound was placed in a container made of stainless steel. An argon (Ar) carrier gas flowed at a flow rate of about 200 sccm to supply the composition for forming a film in a gaseous state to a reaction chamber at room temperature while the process pressure of the reactor was set to 4 Torr.

In order to confirm the deposition characteristics of each silicon-containing oxide film, the gas supply cycle was repeated 100 times, in which the composition for forming a film in a gases state was supplied for about 3 seconds; argon (Ar) gas was supplied for about 10 seconds to remove the composition for forming a film (gas) remaining in the reactor; ozone (O₃) was supplied as a reaction gas for about 5 seconds; and argon (Ar) gas was supplied for about 10 seconds to remove ozone (O₃) remaining in the reactor.

The thickness of each oxide film formed using the composition for forming a silicon-containing film prepared by the methods of the Examples and Comparative Examples was measured using an ellipsometer (M-2000, J. A. Woollam).

Thereafter, the measured thickness was divided by the number of gas supply cycles (100 times) to calculate the growth per cycle (GPC) of ALD gas supply.

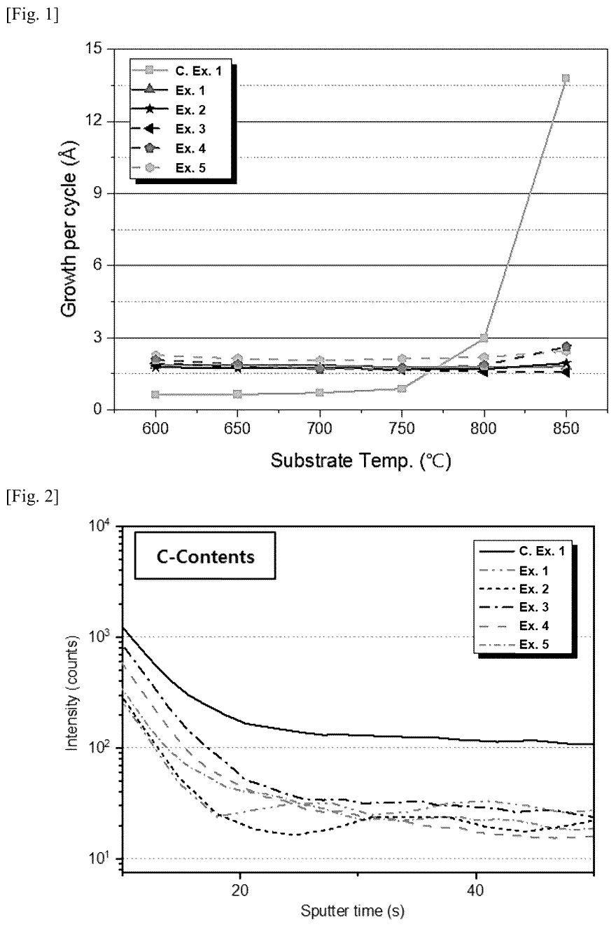

Specifically, the growth per cycle (GPC) of ALD gas supply with respect to a temperature (process temperature) of 600° C. to 850° C. was measured. The results are shown in FIG. 1 and Table 1.

TABLE 1

| | Growth per cycle (GPC) of ALD gas supply (Å/cycle) | | | | | |
|---|---|---|---|---|---|---|
| Deposition | Ex. 1 | Ex. 2 | Ex. 3 | Ex. 4 | Ex. 5 | C. Ex. 1 |
| temp. (° C.) | Formula 1-1 | Formula 1-2 | Formula 1-4 | Formula 1-5 | Formula 1-12 | 3DMAS |
| 600 | 1.86 | 1.78 | 1.93 | 2.07 | 2.27 | 0.62 |
| 650 | 1.88 | 1.73 | 1.80 | 1.89 | 2.14 | 0.64 |
| 700 | 1.86 | 1.76 | 1.71 | 1.69 | 2.06 | 0.71 |
| 750 | 1.77 | 1.68 | 1.66 | 1.74 | 2.13 | 0.88 |
| 800 | 1.78 | 1.69 | 1.59 | 1.85 | 2.19 | 2.97 |
| 850 | 1.81 | 1.95 | 1.57 | 2.63 | 2.45 | 13.78 |

As can be seen from Table 1 and FIG. 1, when ALD was carried out at a high temperature of 600° C. or higher, the GPC was constant at a relatively high temperature of 600° C. to 850° C. as compared with the case where the composition for forming a silicone-containing film comprising the silicone compound of Comparative Example 1 was used.

Specifically, when the composition for forming a silicon-containing film comprising the silicon compound of Comparative Example 1 was used, the growth per cycle (GPC) of ALD gas supply increased from about 700° C. In contrast, when the composition for forming a silicon-containing film comprising the silicon compound of each of Examples 1, 2, 3, 4, and 5 was used, the growth per cycle (GPC) of ALD gas supply was constant even at a high temperature of 800° C. to 850° C. It was confirmed from the above that the composition for forming a silicone-containing film comprising the silicone compound of the Examples of the present invention achieves a constant GPC at a high temperature of 600° C. to 850° C. and shows self-limiting film growth characteristics; thus, it is a precursor suitable for an ALD process at high temperatures.

### <Test Example 2> Analysis of the Physical Properties of a Silicon-Containing Oxide Film Deposited at High Temperatures

The composition for forming a silicon-containing film comprising the silicon compound of each of Examples 1, 2, 3, 4, and 5 and Comparative Example 1 was used to form a SiO₂ film having the same thickness on a flat wafer at 750° C. as the ALD gas supply cycle was adjusted. Its physical and chemical properties were analyzed.

Specifically, the shrinkage and wet etch rate (WER, Å/s) of the SiO₂ film were measured. The thickness of the SiO₂ film was measured with an ellipsometer (M-2000, J. A. Woollam).

The thickness of the silicon-containing film (SiO₂ film) having an initial thickness of about 100 Å formed on a flat wafer at 750° C., as shown in Table 2, by adjusting the ALD gas supply cycle was compared with the thickness of the silicon-containing film (SiO₂ film) upon annealing in an argon (Ar) atmosphere at 750° C. for 60 minutes to calculate the shrinkage according to Equation 1.

$$Shrinkage ( {S}_{750} , \% ) = \frac{A - B}{A} \times 100 \qquad [ Equation 1 ]$$

In Equation 1, A is the initial thickness (Å) of a silicon-containing film formed by ALD at 750° C., and B is the thickness (Å) of the silicon-containing film formed by ALD at 750° C. after it is left at 750° C. in an argon (Ar) atmosphere for 60 minutes.

The results are shown in Table 2.

TABLE 2

| | Ex. 1 | Ex. 2 | Ex. 3 | Ex. 4 | Ex. 5 | |
|---|---|---|---|---|---|---|
| | Formula | Formula | Formula | Formula | Formula | C. Ex. 1 |
| Compound | 1-1 | 1-2 | 1-4 | 1-5 | 1-12 | 3DMAS |
| Initial thickness (Å) of a SiO₂ film | 102.1 | 101.5 | 99.8 | 103.5 | 104.1 | 101.8 |
| formed by ALD at 750° C. (A) | | | | | | |
| Thickness (Å) of the SiO₂ film | 98.15 | 98.06 | 97.1 | 98.95 | 99.96 | 95.28 |
| formed by ALD at 750° C. after it | | | | | | |
| was left at 750° C. in an argon (Ar) | | | | | | |
| atmosphere for 60 minutes (B) | | | | | | |
| Shrinkage (S₇₅₀, %) | 3.87 | 3.39 | 2.71 | 4.40 | 3.98 | 6.40 |

As can be seen from Table 2 above, the shrinkage of the silicon-containing oxide film (SiO₂ film) deposited using the composition for forming a silicon-containing film of each of Examples 1, 2, 3, 4, and 5 was 3.87%, 3.39%, 2.71%, 4.40%, and 3.98%, respectively. In contrast, the shrinkage of the silicon-containing oxide film deposited using the composition for forming a silicon-containing film of Comparative Example 1 was 6.40%. As such, the silicon-containing oxide film deposited using the composition for forming a silicon-containing film of each of Examples 1, 2, 3, 4, and 5 had a smaller shrinkage than that of the silicon-containing oxide film deposited using the composition for forming a silicon-containing film of Comparative Example 1.

Meanwhile, the silicon-containing film (SiO₂ film) having an initial thickness of about 500 Å formed on a flat wafer at 750° C., as shown in Table 4 below, by adjusting the ALD gas supply cycle was etched in a 1% dilute HF solution for 30 seconds. The thickness change was measured to calculate the wet etch rate (WER, Å/s) according to Equation 2.

$$Wet etch rate ( Å / s ) = etch thickness change ( Δ E , Å ) / 30 s \qquad [ Equation 2 ]$$

The etch thickness change (ΔE) may be represented by the following Equation 2-1.

$$Etch thickness change ( Δ E , Å ) = {E}_{A} - {E}_{B} \qquad [ Equation 2 ‐ 1 ]$$

In Equation 2-1, E_{A} is the initial thickness (Å) of a silicon-containing film formed by ALD at 750° C., and E_{B} is the thickness (Å) of the silicon-containing film formed by ALD at 750° C. after it is etched in a 1% dilute HF solution for 30 seconds.

In Equation 2, “s” means seconds.

The results are shown in Table 3.

TABLE 3

| | Ex. 2 | Ex. 3 | Ex. 4 | |
|---|---|---|---|---|
| | Formula | Formula | Formula | C. Ex. 1 |
| Compound | 1-2 | 1-4 | 1-5 | 3DMAS |
| Initial thickness (Å) of a SiO₂ film | 498.3 | 499.2 | 493.4 | 503.4 |
| formed by ALD at 750° C. (E_{A}) | | | | |
| Thickness (Å) of the SiO₂ film | 424.8 | 425.7 | 431.3 | 416.4 |
| formed by ALD at 750° C. after it | | | | |
| was etched in a 1% dilute HF | | | | |
| solution for 30 seconds (E_{B}) | | | | |
| Wet etch rate (E_{A} − E_{B})/30 s (Å/s) | 2.45 | 2.45 | 2.07 | 2.90 |

As can be seen from Table 3 above, the wet etch rate of the silicon-containing oxide film (SiO₂ film) deposited using the composition for forming a silicon-containing film of each of Examples 2, 3, and 4 was 2.45 Å/s, 2.45 Å/s, and 2.07 Å/s, respectively. In contrast, the wet etch rate of the silicon-containing oxide film deposited using the composition for forming a silicon-containing film of Comparative Example 1 was 2.90 Å/s. The silicon-containing oxide film deposited using the composition for forming a silicon-containing film of each of Examples 2, 3, and 4 was decreased.

Meanwhile, in order to confirm impurities in the silicon-containing oxide layer, secondary ion mass spectrometry (SIMS) was carried out for the silicon-containing oxide film.

FIG. 2 is a graph showing the results of secondary ion mass spectrometry (SIMS) of a silicon-containing oxide film deposited at a temperature of 750° C. using the composition for forming a silicon-containing film of Examples 1, 2, 3, 4, and 5 and Comparative Example 1 of the present invention.

In order to confirm impurities in the silicon-containing oxide layer deposited using the composition for forming a silicon-containing film of each of Examples 1, 2, 3, 4, and 5 and Comparative Example 1, the silicon-containing oxide film deposited to a thickness of about 100 Å was analyzed for a carbon (C) content by SIMS.

As a result, the carbon content was reduced by about 80% in Example 1, about 81% in Example 2, about 76% in Example 3, about 81% in Example 4, and about 83% in Example 5, as compared with Comparative Example 1, indicating that a pure silicon-containing oxide film with less than 100 counts of carbon content was formed.

FIG. 3 is a transmission electron microscope (TEM) image of the silicon-containing oxide film formed on a wafer with a deep pattern at 750° C. by ALD using the composition for depositing a silicon-containing film of each of Example 2 and Comparative Example 1 of the present invention and ozone. Table 4 shows the thickness of the silicon-containing oxide film measured in the part shown in FIG. 3.

TABLE 4

| | Ex. 2 | C. Ex. 1 |
|---|---|---|
| Compound | Formula 1-3 | 3DMAS |
| Thickness (Å) measured at the top | 28.4 | 28.6 |
| of the groove | 28.5 | 28.4 |
| | 28.8 | 30.6 |
| Average thickness (Å) measured at the | 28.6 | 29.2 |
| top of the groove (A) | | |
| Thickness (Å) measured at the bottom | 26.7 | 22.3 |
| of the groove | 26.9 | 22.2 |
| | 26.5 | 23.9 |
| Average thickness (Å) measured at the | 26.7 | 22.8 |
| bottom of the groove (B) | | |
| Step coverage (%) (B/A × 100 (%)) | 93.4% | 78.1% |

As can be seen from Table 4, when the composition for forming a silicon-containing film of each of Example 2 and Comparative Example 1 was deposited on a substrate having a step and then analyzed using TEM, the step coverage of the silicon-containing oxide film deposited using the composition for forming a silicon-containing film of Example 2 was 93.4%, whereas the step coverage of the silicon-containing oxide film deposited using the composition for forming a silicon-containing film of Comparative Example 1 was 78.1%. The silicon-containing oxide film deposited using the composition for forming a silicon-containing film of Example 2 had a remarkably excellent step coverage as compared with the silicon-containing oxide film deposited using the composition for forming a silicon-containing film of Comparative Example 1.

In sum, according to the method for forming a silicon-containing film using the composition for forming a silicon-containing film comprising the silicon precursor compound according to an embodiment of the present invention, it was possible to readily deposit a silicon-containing film by ALD, to precisely control the film thickness and composition, and to form a uniform film with excellent coverage even on a substrate having a complex shape.

In particular, according to the method for forming a silicon-containing film using the composition for forming a silicon-containing film comprising the silicon precursor compound according to the present invention, it is possible to obtain a film of a desired thickness at a high temperature of 600° C. to 850° C. during deposition. The silicon-containing oxide film thus obtained had significantly improved physical properties, such as step coverage, shrinkage, and wet etch rate, as compared with the silicon-containing oxide film using the composition for forming a silicon-containing film comprising the silicon precursor compound of Comparative Example 1.

1. A method for forming a silicon-containing film, which comprises depositing a silicon-containing film on a substrate using a composition for forming a silicon-containing film comprising a silicon precursor compound represented by the following Formula 1 by chemical vapor deposition (CVD) or atomic layer deposition (ALD),
wherein the silicon-containing film comprises at least one selected from the group consisting of a silicon-containing oxide film and a silicon-containing composite metal oxide film, and the deposition is carried out at a temperature of 600° C. or higher: 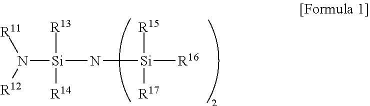
in Formula 1,
R¹¹ and R¹² are each independently selected from the group consisting of hydrogen and a linear or branched C₁-C₄ alkyl group, and
R¹³ to R¹⁷ are each independently selected from the group consisting of hydrogen, a linear or branched C₁-C₄ alkyl group, and a linear or branched C₂-C₆ alkenyl group, provided that at least one of R¹³ and R¹⁴ is not hydrogen; and that at least one of R¹⁵ to R¹⁷ is not hydrogen.

2. The method for forming a silicon-containing film of claim 1, wherein the silicon precursor compound comprises at least one selected from the group consisting of compounds represented by the following Formulae:

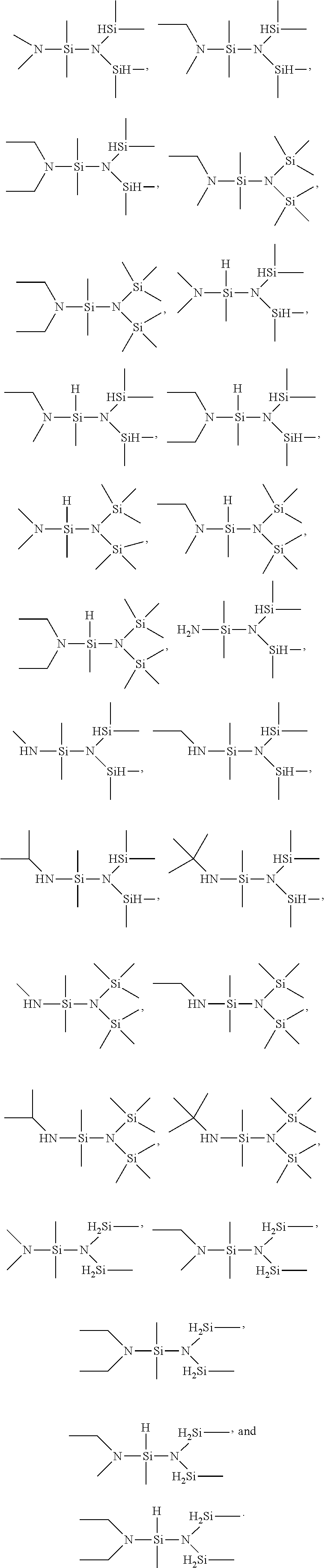

3. The method for forming a silicon-containing film of claim 1, wherein the deposition is carried out in a temperature range of 600° C. to 850° C.

4. The method for forming a silicon-containing film of claim 1, wherein when the deposition is carried out by atomic layer deposition (ALD) using the composition for forming a silicon-containing film, it has a growth per cycle (GPC) of ALD gas supply of 1.5 to 3.0 Å/cycle in a temperature range of 600° C. to 850° C.

5. The method for forming a silicon-containing film of claim 1, wherein at least one selected from the group consisting of water vapor (H₂O), oxygen (O₂), oxygen plasma (O₂ plasma), nitric oxide (NO, N₂O), nitric oxide plasma (N₂O plasma), oxygen nitrate (N₂O₂), hydrogen peroxide (H₂O₂), and ozone (O₃) is used during the deposition.

6. The method for forming a silicon-containing film of claim 1, wherein the silicon-containing film is formed in a thickness range of 1 nm to 500 nm.

7. The method for forming a silicon-containing film of claim 1, wherein the silicon-containing film is formed on a substrate having at least one irregularity having an aspect ratio of 1 or more and a width of 1 μm or less.

8. The method for forming a silicon-containing film of claim 1, wherein the method for forming a silicon-containing film comprises supplying the silicon precursor compound into a reaction chamber using at least one method selected from the group consisting of a bubbling method; a liquid delivery system (LDS) method; a vapor flow control (VFC) method; and a bypass method.

9. The method for forming a silicon-containing film of claim 8, wherein the supplying of the silicon precursor compound into a reaction chamber is carried out using a transport gas or a diluent gas in a temperature range of room temperature to 150° C. and 0.1 to 10 Torr.

10. The method for forming a silicon-containing film of claim 1, wherein, during deposition, thermal energy or plasma is used, or a bias is applied onto the substrate.

11. A composition for forming a silicon-containing film, which comprises a silicon precursor compound represented by the following Formula 1,
wherein the composition is used to deposit a silicon-containing film at a temperature of 600° C. to or higher by chemical vapor deposition (CVD) or atomic layer deposition (ALD), and
the silicon-containing film comprises at least one selected from the group consisting of a silicon-containing oxide film and a silicon-containing composite metal oxide film: 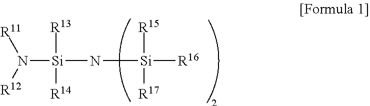
in Formula 1,
R¹¹ and R¹² are each independently selected from the group consisting of hydrogen and a linear or branched C₁-C₄ alkyl group, and
R¹³ to R¹⁷ are each independently selected from the group consisting of hydrogen, a linear or branched C₁-C₄ alkyl group, and a linear or branched C₂-C₆ alkenyl group, provided that at least one of R¹³ and R¹⁴ is not hydrogen; and that at least one of R¹⁵ to R¹⁷ is not hydrogen.

12. The composition for forming a silicon-containing film of claim 11, wherein the silicon precursor compound comprises at least one selected from the group consisting of compounds represented by the following Formulae:

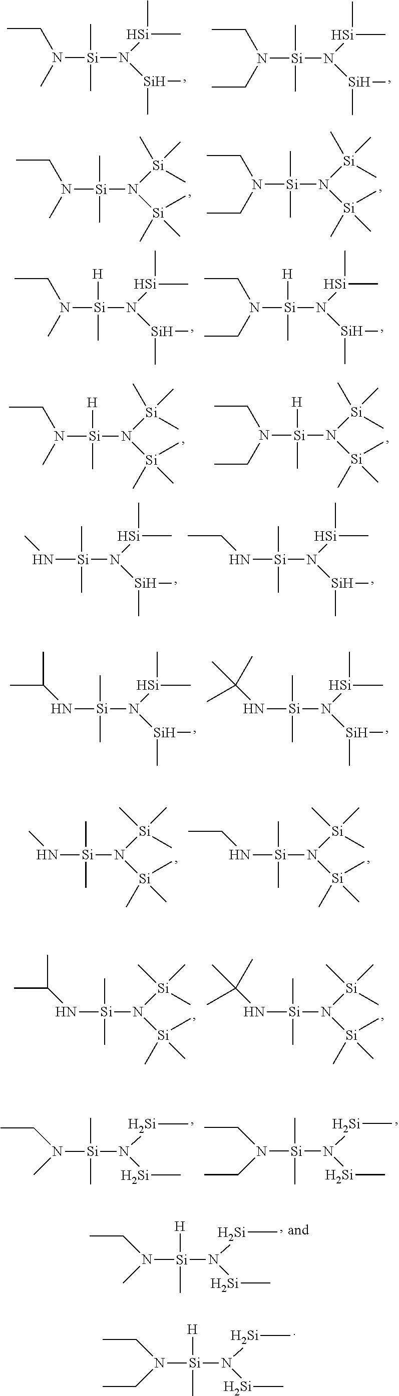

13. A silicon-containing film formed by the method for forming a silicon-containing film of claim 1.

14. The silicon-containing film of claim 13, wherein the shrinkage (S₇₅₀) represented by the following Equation 1 is 5.0% or less:
$$Shrinkage ( {S}_{750} , \% ) = \frac{A - B}{A} \times 100 \qquad [ Equation 1 ]$$
in Equation 1, A is the initial thickness (Å) of a silicon-containing film formed by ALD at 750° C., and B is the thickness (Å) of the silicon-containing film formed by ALD at 750° C. after it is left at 750° C. in an argon (Ar) atmosphere for 60 minutes.

15. The silicon-containing film of claim 13, wherein the silicon-containing film is formed by deposition at 750° C. to a thickness of 500 Å, and
when the thickness of the silicon-containing film is measured with an ellipsometer before and after the silicon-containing film is exposed to an etching solution of 1% dilute hydrofluoric acid, the wet etch rate (Å/s) of the silicon-containing film represented by the following Equation 2 is 4.0 Å/s or less:
$$Wet etch rate ( Å / s ) = etch thickness change ( Δ E , Å ) / 30 s \qquad [ Equation 2 ]$$
wherein the etch thickness change (ΔE) is represented by the following Equation 2-1:
$$Etch thickness change ( Δ E , Å ) = {E}_{A} - {E}_{B} \qquad [ Equation 2 ‐ 1 ]$$
in Equation 2-1, E_{A} is the initial thickness (Å) of a silicon-containing film formed by ALD at 750° C., and ER is the thickness (Å) of the silicon-containing film formed by ALD at 750° C. after it is etched in a 1% dilute HF solution for 30 seconds.
